(19) United States
(12) Patent Application Publication
(10) Pub. No.: US 2026/0095025 A1
(43) Pub. Date: Apr. 2, 2026

(54) Epitaxial Chip Structure

(71) Applicant: NARVELLUX TECHNOLOGY (SHENZHEN) CO., LTD., Shenzhen (CN)

(72) Inventors: Chunhui Yan, Shenzhen (CN); Jingting He, Shenzhen (CN); Yanhao Du, Shenzhen (CN); Wei Sun, Shenzhen (CN); Anli Yang, Shenzhen (CN); Dawei Nie, Shenzhen (CN); Zengliang Zhong, Shenzhen (CN)

(21) Appl. No.: 19/111,334

(22) PCT Filed: Sep. 14, 2023
(86) PCT No.: PCT/CN2023/118927

§ 371 Date: Mar. 13, 2025

(30) Foreign Application Priority Data
Sep. 15, 2022 (CN) 202211124726.7

(51) Int. Cl. H01S 5/34

(52) U.S. Cl. CPC H01S 5/3403

(57) ABSTRACT

Provided is an epitaxial chip structure. The epitaxial chip structure includes a substrate, a preparation layer, a buffer layer, a base layer, and an active layer, where the preparation layer, the buffer layer, the base layer, and the active layer are sequentially stacked on the substrate. The buffer layer is arranged as a multilayer In component gradient growth structure of InₓGa_{y}Al_{z}N (0<x≤100%; x+y+z=1) compound material, and the lattice constant of a material of the buffer layer is the same as or similar to the lattice constant of a material of the active layer.

### CROSS-REFERENCE TO RELATED APPLICATIONS

This application is the United States national phase of International Patent Application No. PCT/CN2023/118927 filed on Sep. 14, 2023, and claims priority to Chinese Patent Application No. 202211124726.7, filed on Sep. 15, 2022, the disclosures of which are hereby incorporated by reference in their entireties.

### BACKGROUND

### Technical Field

The present application relates to the field of semiconductor technology and, in particular, to an epitaxial chip structure that may be applied to semiconductor devices such as semiconductor optoelectronic devices (light-emitting diodes (LEDs)/laser diode (LD) laser/photovoltaics (PV)), power devices, and radio frequency microwave devices.

### Technical Considerations

At present, the third generation of semiconductor devices may include semiconductor optoelectronic devices, power devices, radio frequency microwave devices, and others. In the existing preparation process, sapphire or silicon (Si) is usually used as a substrate, and a material layer containing indium gallium nitride (InGaN) is used as an active layer of a corresponding semiconductor device. For example, in the preparation process of a semiconductor optoelectronic device, a sapphire substrate is usually used, and a multiple quantum well (MQW) layer including an active region is grown on the sapphire substrate. The MQW layer is a multilayer structure formed by the alternating growth of two different semiconductor material thin layers, where one is a quantum well layer, and the other one is a quantum barrier layer. However, for the semiconductor device containing an indium (In) component, the lattice mismatch between the active layer and the sapphire substrate is too large, making it difficult for the semiconductor device to grow a high-quality and high-In component active layer on the substrate.

### SUMMARY

The present disclosure provides an epitaxial chip structure. The epitaxial chip structure includes a substrate; and a buffer layer and an active layer that are stacked sequentially on the substrate, where the buffer layer is arranged as a multilayer indium (In) component gradient growth structure of InₓGa_{y}Al_{z}N (0<x≤100%; x+y+z=1) compound material, and a lattice constant of a material of the buffer layer is the same as or similar to a lattice constant of a material of the active layer.

In non-limiting embodiments, the buffer layer includes at least two In composition buffer layers with a growth temperature changing gradually or in steps.

In non-limiting embodiments, the epitaxial chip structure further includes a preparation layer arranged between the substrate and the buffer layer.

In non-limiting embodiments, the preparation layer includes at least one of aluminum nitride, graphene, gallium oxide, aluminum oxide, silicon carbide, or diamond.

In non-limiting embodiments, the buffer layer is one of an indium gallium nitride (InGaN) material, an indium gallium aluminum nitride (InGaAlN) material, or an indium nitride (InN) material, that is, InₓGa_{y}Al_{z}N (0<x≤100%; x+y+z=1); or the buffer layer is a mixture of at least two materials, that is, the buffer layer is a composite buffer layer.

In non-limiting embodiments, the epitaxial chip structure further includes a base layer arranged as at least one layer of the InₓGa_{y}Al_{z}N (0<x≤100%; x+y+z=1) compound material, where the base layer is adjacent to the active layer, and a growth temperature of the base layer is higher than a growth temperature of the buffer layer.

In non-limiting embodiments, the growth temperature of the buffer layer ranges from 300° C. to 600° C., and the growth temperature of the base layer ranges from 400° C. to 1000° C.

In non-limiting embodiments, a content of an In component in group 3 elements in the InₓGa_{y}Al_{z}N (0<x≤100%; x+y+z=1) compound material in the buffer layer and/or the base layer gradually increases or decreases along a direction from the buffer layer to the active layer.

In non-limiting embodiments, a mole percent of an In component in group 3 elements in the InₓGa_{y}Al_{z}N (0<x≤100%; x+y+z=1) compound material in the buffer layer and/or the base layer is greater than 0% and less than or equal to 100%.

In non-limiting embodiments, the buffer layer includes at least two buffer sub-layers stacked, and a content of an In component in group 3 elements in the InₓGa_{y}Al_{z}N (0<x≤100%; x+y+z=1) compound material in different buffer sub-layers gradually increases or decreases along the direction from the buffer layer to the active layer.

In non-limiting embodiments, the base layer includes at least two base sub-layers stacked, and a content of an In component in group 3 elements in the InₓGa_{y}Al_{z}N (0<x≤100%; x+y+z=1) compound material in different base sub-layers gradually increases or decreases along the direction from the buffer layer to the active layer.

In non-limiting embodiments, a thickness of the buffer layer ranges from 10 nm to 100 nm, a thickness of the base layer ranges from 1 μm to 20 μm, and a thickness of the preparation layer ranges from 1 nm to 100 nm.

In non-limiting embodiments, the base layer is n-type doped; or the buffer layer and the base layer are both n-type doped.

In non-limiting embodiments, at least one base sub-layer facing the active layer is doped with silicon (Si).

In non-limiting embodiments, a surface of one side of the substrate facing the buffer layer is provided with a rough structure.

In non-limiting embodiments, the rough structure is ordered steps or a porous structure and formed by electrochemical etching or photolithography.

In non-limiting embodiments, the surface of the side of the substrate facing the buffer layer is provided with the porous structure and has a duty cycle greater than 5% and less than 80%.

In non-limiting embodiments, a surface of one side of the preparation layer facing the buffer layer is provided with the porous structure and has the duty cycle greater than 5% and less than 80%; and/or a surface of one side of the buffer layer facing the base layer is provided with the porous structure and has the duty cycle greater than 5% and less than 80%; and/or a surface of one side of the base layer facing the active layer is provided with the porous structure and has the duty cycle greater than 5% and less than 80%.

In non-limiting embodiments, the preparation layer includes a multilayer structure with gradient n-type doping.

In non-limiting embodiments, the substrate includes at least one of silicon, silicon carbide, aluminum nitride, gallium nitride, gallium oxide, indium oxide, diamond, germanium, or a sapphire substrate.

In non-limiting embodiments, the buffer layer includes an InN material, the base layer includes an InGaN material or the InN material, and the buffer layer, the base layer, and the active layer are stacked sequentially.

In non-limiting embodiments, the buffer layer includes at least two buffer sub-layers stacked, and a growth temperature of the at least two buffer sub-layers changes gradually or in steps; and the base layer includes at least two base sub-layers stacked, and a growth temperature of the at least two base sub-layers changes gradually or in steps.

In non-limiting embodiments, the preparation layer includes at least one layer of aluminum nitride (AlN) material.

In non-limiting embodiments, a content of In in different buffer sub-layers gradually increases or decreases along a direction from the buffer layer to the active layer; and a content of In in different base sub-layers gradually increases or decreases along the direction from the buffer layer to the active layer.

In non-limiting embodiments, the buffer layer includes at least two buffer sub-layers stacked; a growth temperature of the at least two buffer sub-layers changes gradually or in steps, and a content of In in the at least two buffer sub-layers along a direction from the buffer layer to the active layer is a step-grading structure.

### BRIEF DESCRIPTION OF THE DRAWINGS

To illustrate technical solutions in the non-limiting embodiments of the present application more clearly, drawings used in the description of these embodiments are briefly described below. Further, the drawings described below illustrate part of the embodiments of the present application. Those of ordinary skill in the art may further obtain other drawings based on these drawings.

FIG. 1 is a diagram illustrating the structure of an epitaxial chip structure according to a first non-limiting embodiment according to the principles of the present application;

FIG. 2 is a diagram illustrating the structure of an epitaxial chip structure according to a second non-limiting embodiment according to the principles of the present application;

FIG. 3 is a diagram illustrating the structure of an epitaxial chip structure according to a third non-limiting embodiment according to the principles of the present application; and

FIG. 4 is a diagram illustrating the structure of an epitaxial chip structure according to a fourth non-limiting embodiment according to the principles of the present application.

### DETAILED DESCRIPTION

For a better understanding of the technical solutions of the present application by those skilled in the art, an epitaxial chip structure provided in the present application is described in further detail below in conjunction with the drawings and specific and non-limiting embodiments. It is to be understood that the described embodiments are part, not all, of the embodiments of the present application. Based on the embodiments of the present application, all other embodiments obtained by those of ordinary skill in the art are within the scope of the present application.

Terms such as “first” and “second” in the present application are used for distinguishing different objects rather than to describe a specific order. In addition, terms “including”, “having”, and any variations thereof are intended to encompass a non-exclusive inclusion. For example, a process, method, system, product or device that includes a series of steps or units not only includes the listed steps or units but may further optionally include steps or units that are not listed or inherent to such process, method, product or device.

The present application provides an epitaxial chip structure to solve the problem in the related art that a high-In component active layer is difficult to grow on a sapphire substrate.

Referring to FIG. 1, FIG. 1 is a diagram illustrating the structure of an epitaxial chip structure according to a first embodiment of the present application. As shown in FIG. 1, the epitaxial chip structure 10 includes a substrate 11, a buffer layer 12, and an active layer 13. The active layer 13 may be a function layer corresponding to different semiconductor devices. For example, in a semiconductor optoelectronic device, the active layer 13 may be an MQW layer; in a power device, the active layer 13 may be a doped conductive layer; in a radio frequency microwave device, the active layer 13 may be a signal transmitting layer or a signal receiving layer.

Specifically, the semiconductor optoelectronic device is used as an example in the present application to specifically explain the epitaxial chip structure 10 of the present application. When the epitaxial chip structure 10 of the present application is applied to the semiconductor optoelectronic device, the active layer 13 of the present application is specifically the MQW layer. The MQW layer includes a quantum barrier layer and a quantum well layer, where the quantum barrier layer is a gallium nitride (GaN) material, and the quantum well layer is an InGaN material; the mole percent of the In component in the quantum well layer may be adjusted according to the wavelength of light to be modulated. For example, when the manufactured epitaxial chip structure 10 is used for generating red light, the mole percent content of the In component in group 3 elements in an InGaAlN material of the quantum well layer is about 40%; when the manufactured epitaxial chip structure 10 is used for generating green light, the mole percent content of the In component in the group 3 elements in the InGaAlN material of the quantum well layer is about 25%. In non-limiting embodiments, a single quantum well layer and a single quantum barrier layer form a cycle, and the active layer 13 may be provided with multiple cycles alternately stacked, where the number of cycles of alternately stacked quantum well layers and quantum barrier layers may be from 2 cycles to 1000 cycles.

Specifically, the buffer layer 12 and the active layer 13 are sequentially stacked on the substrate 11. The buffer layer 12 is arranged as a multilayer In component gradient growth structure, and a lattice constant of the material of the buffer layer 12 is the same as or similar to a lattice constant of the material of the active layer 13. The multilayer In component gradient growth structure includes at least two In composition buffer layers with a growth temperature changing gradually or in steps. The buffer layer 12 is arranged as a multilayer InₓGa_{y}Al_{z}N (0<x≤100%; x+y+z=1) compound stacked layer. In non-limiting embodiments, an In composition is at least one of an InGaN material, an InGaAlN material, or an InN material, and when the In composition has multiple materials, the buffer layer 12 is a composite buffer layer. In non-limiting embodiments, the composite buffer layer may be a superlattice structure.

In non-limiting embodiments, the buffer layer 12 may include one layer of InN material and at least one layer of InGaN material or InGaAlN material, where the one layer of InN material is grown on the substrate 11, and the at least one layer of InGaN material or InGaAlN material is further grown on the one layer of InN material. In this embodiment, the one layer of InN material is grown on the substrate 11, and the one layer of InGaN material or InGaAlN material having the same In component can also be better grown on the one layer of InN material so that the MQW layer also having the In component can be better grown on the one layer of InGaN material or InGaAlN material to obtain the epitaxial chip structure 10 on which the high-In component and high-quality MQW layer is grown.

In the related art, for a long-wavelength GaN-based LED, sapphire is usually used as the material of the substrate, and low-temperature GaN/AlN is usually used as the material of the buffer layer. The lattice constant of the substrate is smaller than that of the buffer layer and that of a quantum well in MQW. When the quantum well with a high In component is subjected to great compressive stress from the substrate and the buffer layer, In precipitation and phase separation occur. In addition, the material of the buffer layer is different from that of the MQW layer, making it difficult for the MQW layer to grow on the buffer layer, which in turn affects the light emission efficiency of the LED.

Therefore, in this embodiment, one buffer layer 12 is grown between the substrate 11 and the active layer 13; the buffer layer 12 is arranged as the multilayer In component gradient growth structure, and the lattice constant of the material of the buffer layer 12 is the same as or similar to the lattice constant of the material of the active layer 13 so that the active layer 13 that also has the In component can be grown on the buffer layer 12 with high quality. For another aspect, the lattice constant of the material of the buffer layer 12 is the same as or similar to the lattice constant of the material of the active layer 13 so that the lattice constant of the buffer layer 12 can match the lattice constant of the active layer 13, and the active layer 13 can be conveniently grown on the buffer layer 12, thereby effectively improving the growth quality of the active layer 13.

As shown in FIG. 1, the epitaxial chip structure 10 further includes a base layer 15. The buffer layer 12, the base layer 15, and the active layer 13 are sequentially stacked and grown on the substrate 11, that is, the buffer layer 12 is arranged adjacent to the substrate 11, and the base layer 15 is arranged adjacent to the active layer 13. The base layer 15 is arranged to include at least one layer of InₓGa_{y}Al_{z}N (0<x≤100%; x+y+z=1) compound material.

Specifically, in this embodiment, the growth temperature of the buffer layer 12 is lower than the growth temperature of the base layer 15. The growth temperature of the buffer layer 12 ranges from 300° C. to 600° C., and the growth temperature of the base layer 15 ranges from 400° C. to 1000° C. Since the growth stresses corresponding to InGaN growing at high and low temperatures are different, the growth stresses of the buffer layer 12 and the base layer 15 in this embodiment are also different.

Specifically, in this embodiment, the content of the In component in group 3 elements in the InₓGa_{y}Al_{z}N (0<x≤100%; x+y+z=1) compound material in the buffer layer 12 and/or the base layer 15 gradually increases or decreases along the direction from the buffer layer 12 to the active layer 13. In non-limiting embodiments, the mole percent of the In component in group 3 elements in the InₓGa_{y}Al_{z}N (0<x≤100%; x+y+z=1) compound material in the buffer layer 12 is greater than 0% and less than or equal to 100%, and the mole percent of the In component in group 3 elements in the InₓGa_{y}Al_{z}N (0<x≤100%; x+y+z=1) compound material in the base layer 15 is greater than 0% and less than or equal to 100%. That is, the mole percent of the In component in the group 3 elements in the InₓGa_{y}Al_{z}N (0<x≤100%; x+y+z=1) compound material in the buffer layer 12 changes from 0% to 100% or from 100% to 0% from one side facing the substrate 11 to one side facing the base layer 15; the mole percent of the In component in the group 3 elements in the InₓGa_{y}Al_{z}N (0<x≤100%; x+y+z=1) compound material in the base layer 15 changes from 0% to 100% or from 100% to 0% from one side facing the buffer layer 12 to one side facing the active layer 13.

In this embodiment, the buffer layer 12 and the base layer 15 are each at least one of the InGaN material, the InGaAlN material, or the InN material, that is, the buffer layer 12 and the base layer 15 each include the In component, a gallium (Ga) component, and an aluminum (Al) component. Specifically, the In component, the Ga component, and the Al component are independent components with their contents not affecting each other, and the content of the Ga component and the content of the Al component may be both greater than or equal to 0%.

Specifically, when the content of the Ga component is greater than 0%, and the content of the Al component is greater than 0%, the buffer layer 12 and the base layer 15 are each the InGaAlN material; when the content of the Ga component is greater than 0%, and the content of the Al component is equal to 0%, the buffer layer 12 and the base layer 15 are each the InGaN material; when the content of the Ga component is equal to 0%, and the content of the Al component is equal to 0%, the buffer layer 12 and the base layer 15 are each the InN material.

In this embodiment, the buffer layer 12 with a low growth temperature and a high mole percent of In component is grown on the substrate 11 so that the buffer layer 12 can release stress as much as possible. Moreover, the base layer 15 with the same doping component is further grown on the buffer layer 12, and the base layer 15 has a high growth temperature and a low mole percent of In component so that the base layer 15 can grow well on the buffer layer 12, and thereby the active layer 13 with the same doping component and a similar mole percent of In component can grow well on the base layer 15. In this embodiment, the growth environment of the active layer 13 is improved to reduce the defects of the active layer 13 caused by stress release, thereby improving the light conversion efficiency of the active layer 13.

Specifically, in this embodiment, the thickness of the buffer layer 12 ranges from 10 nm to 100 nm, and the thickness of the base layer 15 ranges from 1 μm to 20 μm. The thickness of the base layer 15 is greater than that of the buffer layer 12, that is, the buffer layer 12 with many lattice defects is thinner than the base layer 15 with few lattice defects so that the active layer 13 can be grown more conveniently on the base layer 15.

In non-limiting embodiments, the buffer layer 12 may be the InN material, the base layer 15 may be the InGaN material or the InN material, and the buffer layer 12, the base layer 15, and the active layer 13 are stacked sequentially.

In this embodiment, the buffer layer 12 that is specifically the InN material is grown on the substrate 11. Since the lattice constant of the InN material is slightly different from that of the substrate 11, the buffer layer 12 is easy to grow on the substrate 11. The base layer 15 having the same In component can also be better grown on the buffer layer 12 so that the active layer 13 also having the In component can be better grown on the base layer 15 to obtain the epitaxial chip structure 10 on which the high-In component and high-quality active layer 13 is grown.

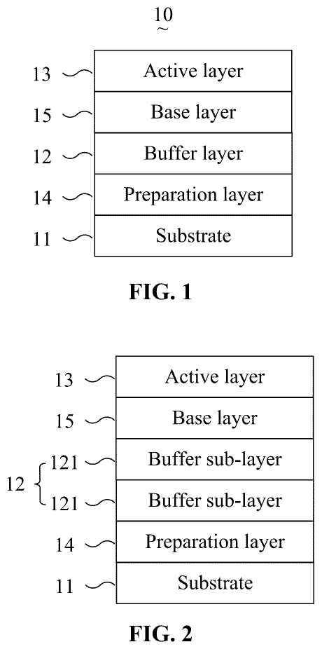

In conjunction with FIG. 1 and further referring to FIG. 2, FIG. 2 is a diagram illustrating the structure of an epitaxial chip structure according to a second non-limiting embodiment of the present application. As shown in FIG. 2, the buffer layer 12 of this embodiment includes at least two buffer sub-layers 121 stacked.

In this embodiment, the content of In in different buffer sub-layers 121 gradually increases or decreases along the direction from the buffer layer 12 to the active layer 13. In other embodiments, the growth temperature of the at least two buffer sub-layers 121 stacked changes gradually or in steps.

Specifically, the thickness of each buffer sub-layer 121 is the same and equal to 1/n the thickness of the buffer layer 12, where n denotes the number of buffer sub-layers 121, that is, the total thickness of the at least two buffer sub-layers 121 remains unchanged and is equal to the thickness of the buffer layer 12.

The content of In in each buffer sub-layer 121 is different, and the content of In in the same buffer sub-layer 121 is the same. For example, the buffer layer 12 may include four buffer sub-layers 121 stacked; the content of In in a first buffer sub-layer 121 is 5%, the content of In in a second buffer sub-layer 121 is 35%, the content of In in a third buffer sub-layer 121 is 65%, and the content of In in a fourth buffer sub-layer 121 is 95%; the first to fourth buffer sub-layers 121 may be stacked along the direction from the substrate 11 to the active layer 13 or the direction from the active layer 13 to the substrate 11.

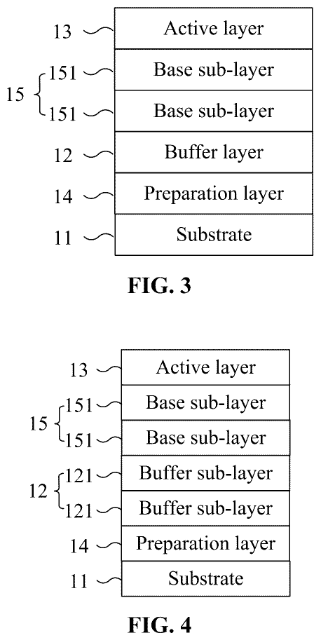

In conjunction with FIG. 1 and further referring to FIG. 3, FIG. 3 is a diagram illustrating the structure of an epitaxial chip structure according to a third non-limiting embodiment of the present application. As shown in FIG. 3, the base layer 15 of this embodiment includes at least two base sub-layers 151 stacked.

In this embodiment, the content of In in different base sub-layers 151 gradually increases or decreases along the direction from the buffer layer 12 to the active layer 13. In other embodiments, the growth temperature of the at least two base sub-layers 151 stacked changes gradually or in steps. In the present application, a change in steps refers to that a growth parameter of each stacked layer, such as temperature or component doping, is not a linear gradient change, but may be a nonlinear change in steps.

Specifically, the thickness of each base sub-layer 151 is the same and equal to 1/n the thickness of the base layer 15, where n denotes the number of base sub-layers 151, that is, the total thickness of the at least two base sub-layers 151 remains unchanged and is equal to the thickness of the base layer 15.

The content of In in each base sub-layer 151 is different, and the content of In in the same base sub-layer 151 is the same. For example, the at least two base layers 15 may include four base sub-layers 151 stacked; the content of In in a first base sub-layer 151 is 10%, the content of In in a second base sub-layer 151 is 20%, the content of In in a third base sub-layer 151 is 30%, and the content of In in a fourth base sub-layer 151 is 40%; the first to fourth base sub-layers 151 may be stacked along the direction from the substrate 11 to the active layer 13 or the direction from the active layer 13 to the substrate 11. The content of In herein refers to the content of the In component in the group 3 elements in the InₓGa_{y}Al_{z}N (0<x≤100%; x+y+z=1) compound material.

As shown in FIG. 1, the base layer 15 and the active layer 13 are stacked, so the base layer 15 may have an n-type function, that is, the base layer 15 may be n-type doped. Specifically, the base layer 15 may be doped with Si to achieve the n-type function. In non-limiting embodiments, since the base layer 15 may include multiple base sub-layers 151, at least one base sub-layer 151 facing the active layer 13 may be doped with Si to enable the base layer 15 to achieve the n-type function.

In non-limiting embodiments, the buffer layer 12 and the base layer 15 may both have the n-type function, that is, the buffer layer 12 and the base layer 15 may be both n-type doped. Specifically, the buffer layer 12 and the base layer 15 may be both doped with Si to achieve the n-type function.

In non-limiting embodiments, the epitaxial chip structure 10 of the present application is applicable to all substrates. The substrate 11 of this embodiment may include at least one of a silicon substrate or the sapphire substrate, and may further include at least one of a silicon carbide (SiC) substrate, an aluminum nitride (AlN) substrate, a diamond substrate, a germanium (Ge) substrate, gallium nitride (GaN), gallium oxide (Ga₂O₃), or indium oxide (In₂O₃). In non-limiting embodiments, the epitaxial chip structure 10 of the present application is further applicable to a composite substrate, specifically, n-GaN grown on a conventional sapphire or another conductive transparent (reflective) heat dissipation substrate.

In non-limiting embodiments, when the substrate 11 is the silicon substrate, and the buffer layer 12 includes at least one InN material layer, since the silicon substrate is an opaque material, and the buffer layer 12 and the active layer 13 are transparent materials, when the epitaxial chip structure 10 of a transparent material is required, the substrate 11 on the epitaxial chip structure 10 may be peeled off. Since the growth temperature of InN is 400° C., the dissociation temperature of InN is 600° C., and the growth temperature of the buffer layer 12 is about 700° C., the growth temperature of the epitaxial chip structure 10 may be arranged greater than 600° C. so that InN can decompose to separate the substrate 11 from the buffer layer 12 and the active layer 13.

As shown in FIG. 1, the epitaxial chip structure 10 of this embodiment further includes a preparation layer 14 arranged between the substrate 11 and the buffer layer 12 arranged as the multilayer In component gradient growth structure. The preparation layer 14 of this embodiment can fulfill the functions of protecting the substrate 11, repairing and improving the growth interface of the buffer layer 12, and preparing for the stress design target of the buffer layer 12. In non-limiting embodiments, when there is no need to protect the substrate, the preparation layer 14 may also not be provided.

In non-limiting embodiments, the preparation layer 14 of this embodiment may be specifically at least one of aluminum nitride (AlN), graphene, gallium oxide (Ga₂O₃), aluminum oxide (Al₂O₃), silicon carbide (SiC), or diamond.

In non-limiting embodiments, the preparation layer 14 of this embodiment includes a multilayer structure with gradient n-type doping. Specifically, when the preparation layer 14 includes at least one layer of AlN material, the buffer layer 12 and the substrate 11 that are specifically InN materials can be isolated by the AlN material to prevent the InN material from corroding the substrate 11, that is, to prevent the InN material from chemically reacting with the silicon substrate, and the growth interface can also be repaired and improved to prepare for the stress design of the buffer layer.

In this embodiment, the preparation layer 14 only serves as an insulation thin film, so the epitaxial chip structure 10 is not required to grow a preparation layer 14 with an excessive thickness, and the growth thickness of the preparation layer 14 may range from 1 nm to 100 nm.

Further, the epitaxial chip structure 10 of the present application may further be provided with a rough structure that may be arranged on the surface of one side of the substrate 11 facing the buffer layer 12. In non-limiting embodiments, the rough structure may be ordered steps or a porous structure and is formed by electrochemical etching or photolithography.

The porous structure may be arranged on at least one of the surface of the side of the substrate 11 facing the buffer layer 12, the surface of one side of the preparation layer 14 facing the buffer layer 12, the surface of one side of the buffer layer 12 facing the base layer 15, or the surface of one side of the base layer 15 facing the active layer 13.

Specifically, if the surface of the side of the substrate 11 facing the buffer layer 12 is provided with the porous structure, the surface of the side of the substrate 11 facing the buffer layer 12 has the duty cycle greater than 5% and less than 80%. The duty cycle is the ratio of a punched region to the total area, that is, the ratio of the punched region to the total area of the substrate 11.

If the surface of the side of the preparation layer 14 facing the buffer layer 12 is provided with the porous structure, the duty cycle of the surface of the side of the preparation layer 14 facing the buffer layer 12 is greater than 5% and less than 80%, where the duty cycle is the ratio of the punched region to the total area of the preparation layer 14.

If the surface of the side of the buffer layer 12 facing the base layer 15 is provided with the porous structure, the duty cycle of the surface of the side of the buffer layer 12 facing the base layer 15 is greater than 5% and less than 80%, where the duty cycle is the ratio of the punched region to the total area of the buffer layer 12.

If the surface of the side of the base layer 15 facing the active layer 13 is provided with the porous structure, the duty cycle of the surface of the side of the base layer 15 facing the active layer is 13 greater than 5% and less than 80%, where the duty cycle is the ratio of the punched region to the total area of the base layer 15.

In the present application, the surface of the side of the substrate 11 facing the buffer layer 12 is provided with the porous structure, and the InN material with the lattice constant that is slightly different from that of the substrate 11 is used as the buffer layer 12 so that the buffer layer 12 can be grown on the substrate 11. On this basis, the buffer layer 12 and the base layer 15 with the same material but different growth temperatures are further grown sequentially so that a high-quality InGaN layer or InGaAlN layer can be obtained and used as a growth preparation layer of the active layer 13. Moreover, based on the fact that the base layer 15 and the active layer 13 have the same material, the lattice constant of the active layer 13 further grown on the high-quality base layer 15 matches the lattice constant of the base layer 15 used as the growth preparation layer so that the high-quality and high-In component active layer 13 can be obtained, thereby solving the In precipitation and the phase separation that are caused by the severe lattice mismatch between the MQW layer of a long-wavelength LED and the substrate of the long-wavelength LED.

The object of the present application is to provide a high-quality epitaxial chip structure 10 containing a thick layer of indium nitride compound and grown under low stress. The epitaxial chip structure 10 establishes a high-quality growth platform containing the indium nitride compound for the growth of the active layer 13 and solves the In precipitation and the phase separation that are caused by the severe lattice mismatch. Combinations of material selection and structure design may include a variety of combinations, as shown in the following table. Among these combinations, the preparation layer 14 may be omitted. In the table, the growth temperature of the buffer layer 12 is lower than that of the base layer 15, and the temperature of the base layer 15 is higher than the growth temperature of the buffer layer 12.

| | | | | Whether |
|---|---|---|---|---|
| | | | | a three- |
| | Prepa- | | | dimensional |
| Serial | ration | | | structure is |
| number | layer | Buffer layer | Base layer | included |
| 1 | AlN or | low-temperature | high-temperature | no |
| | GaN | InN | InN | |
| 2 | graphene | low-temperature | high-temperature | no |
| | | InN | InGaN | |
| 3 | gallium | low-temperature | high-temperature | no |
| | oxide | InN | InGaAlN | |
| 4 | AlN or | low-temperature | high-temperature | no |
| | GaN | InGaAlN | InN | |
| 5 | graphene | low-temperature | high-temperature | no |
| | | InGaAlN | InGaN | |
| 6 | gallium | low-temperature | high-temperature | no |
| | oxide or | InGaAlN | InGaAlN | |
| | indium | | | |
| | oxide | | | |
| 7 | AlN or | low-temperature | high-temperature | porous |
| | GaN | InN | InN | structure |
| 8 | graphene | low-temperature | high-temperature | rough |
| | | InN | InGaN | surface |
| 9 | gallium | low-temperature | high-temperature | strip-shaped |
| | oxide or | InN | InGaAlN | or island- |
| | indium | | | shaped |
| | oxide | | | structure |
| 10 | AlN or | low-temperature | high-temperature | porous |
| | GaN | InGaAlN | InN | structure |
| 11 | graphene | low-temperature | high-temperature | rough |
| | | InGaAlN | InGaN | surface |
| 12 | gallium | low-temperature | high-temperature | strip-shaped |
| | oxide or | InGaAlN | InGaAlN | or island- |
| | indium | | | shaped |
| | oxide | | | structure |

Specifically, further referring to FIG. 4, FIG. 4 is a diagram illustrating the structure of an epitaxial chip structure according to a fourth non-limiting embodiment of the present application. As shown in FIG. 4, the buffer layer 12 of the epitaxial chip structure 10 may include multiple buffer sub-layers 121, and the base layer 15 of the epitaxial chip structure 10 may include multiple base sub-layers 151; a three-dimensional structure arranged on the substrate 11 or on the surface of each layer facing the upper layer is an optional solution. An In component gradient structure and a temperature gradient structure are used for the multiple buffer sub-layers 121 and the multiple base sub-layers 151, where the growth temperature of the base sub-layer 151 is higher than that of the buffer sub-layer 121.

Further, the In component gradient structure may also be a step-grading structure, that is, the In component in each layer changes in steps, and the In component in each layer is evenly distributed.

The preceding embodiments are embodiments of the present application and are not intended to limit the scope of the present application. Any equivalent structural variations or equivalent process variations made on the basis of the Specification and the Drawings of the present application, or direct or indirect utilization in other relevant technical fields all fall within the scope of the present application.

1. An epitaxial chip structure, comprising:
a substrate; and
a buffer layer and an active layer that are stacked sequentially on the substrate,
wherein the buffer layer is arranged as a multilayer indium (In) component gradient growth structure of InₓGa_{y}Al_{z}N (0<x≤100%; x+y+z=1) compound material, and a lattice constant of a material of the buffer layer is the same as or similar to a lattice constant of a material of the active layer; and
the epitaxial chip structure further comprises a base layer arranged as at least one layer of the InₓGa_{y}Al_{z}N (0<x≤100%; x+y+z=1) compound material, wherein the base layer is adjacent to the active layer, and a growth temperature of the base layer is higher than a growth temperature of the buffer layer.

2. The epitaxial chip structure of claim 1, wherein the buffer layer comprises at least two In composition buffer layers with a growth temperature changing gradually or in steps.

3. The epitaxial chip structure of claim 1, further comprising a preparation layer arranged between the substrate and the buffer layer;
wherein the preparation layer comprises at least one of aluminum nitride, graphene, gallium oxide, aluminum oxide, silicon carbide, or diamond, and a thickness of the preparation layer ranges from 1 nm to 100 nm.

4. (canceled)

5. The epitaxial chip structure of claim 2, wherein the buffer layer is one of an indium gallium nitride (InGaN) material, an indium gallium aluminum nitride (InGaAlN) material, or an indium nitride (InN) material; or the buffer layer is a composite buffer layer of at least two materials of an indium gallium nitride (InGaN) material, an indium gallium aluminum nitride (InGaAlN) material, or an indium nitride (InN) material.

6. (canceled)

7. The epitaxial chip structure of claim 1, wherein
the growth temperature of the buffer layer ranges from 300° C. to 600° C., and the growth temperature of the base layer ranges from 400° C. to 1000° C.

8. The epitaxial chip structure of claim 1, wherein a content of an In component in group 3 elements in the InₓGa_{y}Al_{z}N (0<x≤100%; x+y+z=1) compound material in at least one of the buffer layer or the base layer gradually increases or decreases along a direction from the buffer layer to the active layer.

9. The epitaxial chip structure of claim 1, wherein a mole percent of an In component in group 3 elements in the InₓGa_{y}Al_{z}N (0<x≤100%; x+y+z=1) compound material in at least one of the buffer layer or the base layer is greater than 0% and less than or equal to 100%.

10. The epitaxial chip structure of claim 8, wherein the buffer layer comprises at least two buffer sub-layers stacked, and a content of an In component in group 3 elements in the InₓGa_{y}Al_{z}N (0<x≤100%; x+y+z=1) compound material in different buffer sub-layers gradually increases or decreases along the direction from the buffer layer to the active layer.

11. The epitaxial chip structure of claim 8, wherein the base layer comprises at least two base sub-layers stacked, and a content of an In component in group 3 elements in the InₓGa_{y}Al_{z}N (0<x≤100%; x+y+z=1) compound material in different base sub-layers gradually increases or decreases along the direction from the buffer layer to the active layer.

12. The epitaxial chip structure of claim 8, wherein a thickness of the buffer layer ranges from 10 nm to 100 nm, and a thickness of the base layer ranges from 1 μm to 20 μm.

13. The epitaxial chip structure of claim 8, wherein the base layer is n-type doped; or the buffer layer and the base layer are both n-type doped.

14. The epitaxial chip structure of claim 11, wherein at least one base sub-layer facing the active layer is doped with silicon (Si).

15. The epitaxial chip structure of claim 3, wherein a surface of one side of the substrate facing the buffer layer is provided with a rough structure, and the rough structure is ordered steps or a porous structure and formed by electrochemical etching or photolithography.

16. (canceled)

17. The epitaxial chip structure of claim 15, wherein the surface of the side of the substrate facing the buffer layer is provided with the porous structure and has a duty cycle greater than 5% and less than 80%.

18. The epitaxial chip structure of claim 17, wherein at least one of the following configuration is satisfied:
a surface of one side of the preparation layer facing the buffer layer is provided with the porous structure and has the duty cycle greater than 5% and less than 80%;
a surface of one side of the buffer layer facing the base layer is provided with the porous structure and has the duty cycle greater than 5% and less than 80%; or
a surface of one side of the base layer facing the active layer is provided with the porous structure and has the duty cycle greater than 5% and less than 80%.

19. The epitaxial chip structure of claim 3, wherein the preparation layer comprises a multilayer structure with gradient n-type doping.

20. (canceled)

21. The epitaxial chip structure of claim 3, wherein
the buffer layer comprises an InN material, the base layer comprises an InGaN material or the InN material, and the buffer layer, the base layer, and the active layer are stacked sequentially.

22. The epitaxial chip structure of claim 21, wherein at least one of the following configurations is satisfied:
the buffer layer comprises at least two buffer sub-layers stacked, and a growth temperature of the at least two buffer sub-layers changes gradually or in steps; and
the base layer comprises at least two base sub-layers stacked, and a growth temperature of the at least two base sub-layers changes gradually or in steps; or
the preparation layer comprises at least one layer of aluminum nitride (AlN) material.

23. (canceled)

24. The epitaxial chip structure of claim 22, wherein
a content of In in different buffer sub-layers gradually increases or decreases along a direction from the buffer layer to the active layer; and
a content of In in different base sub-layers gradually increases or decreases along the direction from the buffer layer to the active layer.

25. The epitaxial chip structure of claim 21, wherein
the buffer layer comprises at least two buffer sub-layers stacked; a growth temperature of the at least two buffer sub-layers changes gradually or in steps, and a content of In in the at least two buffer sub-layers along a direction from the buffer layer to the active layer is a step-grading structure.
